(19) United States
(12) Patent Application Publication
(10) Pub. No.: US 2023/0371276 A1
(43) Pub. Date: Nov. 16, 2023

(54) MAGNETIC MEMORY DEVICE AND ELECTRONIC DEVICE COMPRISING THE SAME

(71) Applicant: Samsung Electronics Co., Ltd., Suwon-si (KR)

(72) Inventors: Geon Hee Bae, Suwon-si (KR); Seung Pil Ko, Suwon-si (KR); Yoon Jong Song, Suwon-si (KR); Kil Ho Lee, Suwon-si (KR)

(21) Appl. No.: 18/156,570

(22) Filed: Jan. 19, 2023

(30) Foreign Application Priority Data
May 11, 2022 (KR) 10-2022-0057736

(51) Int. Cl. H10B 61/00

(52) U.S. Cl. CPC H10B 61/00; G11C 11/1673

(57) ABSTRACT

A magnetic memory device includes first and second upper insulating layers and a first mold layer sequentially stacked on a first substrate region; a first primary and first secondary wiring structure spaced apart in a first direction in the first upper insulating layer; a second wiring structure on the first primary wiring structure and a reference wiring structure on the first secondary wiring structure, in the second upper insulating layer; a first structure on the second wiring structure; a second structure on the reference wiring structure; a lower electrode contact between the second wiring structure and the first structure, and not between the reference wiring structure and the second structure, in the first mold layer; a bit line structure on the first structure; and a reference bit line structure on the second structure. The first and second structure include a lower electrode, MTJ structure, intermediate electrode, and upper electrode.

### CROSS-REFERENCE TO RELATED APPLICATION

This application claims priority under 35 U.S.C. § 119 from Korean Patent Application No. 10-2022-0057736 Filed on May 11, 2022 in the Korean Intellectual Property Office, the disclosure of which is incorporated herein by reference in its entirety.

### FIELD

The present disclosure relates to a magnetic memory device and an electronic device comprising the same.

### BACKGROUND

Non-volatile memory devices that operate based on a resistance material may include a phase change memory device (PRAM: Phase change Random Access Memory), a resistive memory device (RRAM: Resistive RAM), a magnetic memory device (MRAM: Magnetic RAM), and the like. A dynamic memory device (DRAM: Dynamic RAM) and a flash memory device store data using charges, whereas a non-volatile memory device using the resistance material stores data using a state change (PRAM) of a phase change material such as a chalcogenide alloy, a resistance change (RRAM) of variable resistance material, a resistance change (MRAM) of a MTJ (Magnetic Tunnel Junction) thin film depending on a magnetization state of a ferromagnetic material, and the like.

Magnetic random access memory (MRAM) may provide relatively fast read/write speeds, high endurance, non-volatility, and low power consumption during operation. Further, MRAM may store information using magnetic materials as information storage media.

### SUMMARY

Aspects of the present disclosure provide a magnetic memory device having improved product reliability.

Aspects of the present disclosure also provide an electronic device including a magnetic memory device having improved product reliability.

According to some embodiments of the present disclosure, a magnetic memory device includes a first upper insulating layer, a second upper insulating layer, and a first mold layer that are sequentially stacked on a substrate; a first primary wiring structure and a first secondary wiring structure that are spaced apart from each other in the first upper insulating layer; a second wiring structure on the first primary wiring structure, in the second upper insulating layer; a reference wiring structure on the first secondary wiring structure, in the second upper insulating layer; a first structure on the second wiring structure; a second structure on the reference wiring structure; a lower electrode contact that is between the second wiring structure and the first structure, and is not between the reference wiring structure and the second structure, in the first mold layer; a bit line structure on the first structure; and a reference bit line structure on the second structure, wherein the first structure and the second structure respectively comprise a lower electrode, an MTJ structure, an intermediate electrode, and an upper electrode.

According to some embodiments of the present disclosure, a magnetic memory device includes a first upper insulating layer, a second upper insulating layer, and a first mold layer that are sequentially stacked on a substrate; a first wiring structure and a reference wiring structure that are spaced apart from each other in the first upper insulating layer; a second primary wiring structure on the first wiring structure, in the second upper insulating layer; a second secondary wiring structure on the reference wiring structure, in the second upper insulating layer; a first structure on the second primary wiring structure; a second structure on the second secondary wiring structure; a lower electrode contact in the first mold layer, between the second primary wiring structure and the first structure, and between the second secondary wiring structure and the second structure; a bit line structure on the first structure; and a reference bit line structure on the second structure, wherein the first structure and the second structure respectively comprise a lower electrode, an MTJ structure, an intermediate electrode, and an upper electrode.

According to some embodiments of the present disclosure, an electronic device includes a logic region; and a memory region electrically connected to the logic region, wherein the memory region is embedded in the electronic device, and the memory region comprises a cell region and a core peri region, and wherein the cell region comprises: a substrate; a first upper insulating layer, a second upper insulating layer and a first mold layer that are sequentially stacked on the substrate; a plurality of first primary wiring structures aligned in a first direction in the first upper insulating layer; a plurality of first secondary wiring structures spaced apart from the plurality of first primary wiring structures in a second direction and aligned in the first direction, in the first upper insulating layer; a plurality of second wiring structures on the plurality of first primary wiring structures, respectively, in the second upper insulating layer; a reference wiring structure extending along the first direction and electrically connected to the plurality of first secondary wiring structures, on the plurality of first secondary wiring structures in the second upper insulating layer; a first structure on one or more of the plurality of second wiring structures; a second structure on the reference wiring structure; a lower electrode contact between the one or more of the plurality of second wiring structures and the first structure, in the first mold layer; a bit line structure extending in the first direction on the first structure; and a reference bit line structure extending in the first direction on the second structure, wherein the reference wiring structure and the second structure are spaced apart by the first mold layer, and wherein the first and second structures respectively comprise a lower electrode, an MTJ structure, an intermediate electrode, and an upper electrode.

According to some embodiments of the present disclosure, an electronic device includes a logic region; and a memory region electrically connected to the logic region, wherein the memory region is embedded in the electronic device, and the memory region comprises a cell region and a core peri region, and wherein the cell region comprises: a substrate; a first upper insulating layer, a second upper insulating layer, and a first mold layer that are sequentially stacked on the substrate; a plurality of first primary wiring structures aligned in a first direction, in the first upper insulating layer; a reference wiring structure spaced apart from the plurality of first primary wiring structures in a second direction and extending along the first direction, in the first upper insulating layer; a plurality of second primary wiring structures on the plurality of first primary wiring structures, respectively, in the second upper insulating layer; a plurality of second secondary wiring structures on the reference wiring structure, in the second upper insulating layer; a first structure on one or more of the plurality of second primary wiring structures; a second structure on one or more of the plurality of second secondary wiring structures; a respective lower electrode contact between the one or more of the plurality of second primary wiring structures and the first structure, and between the one or more of the plurality of second secondary wiring structures and the second structure, in the first mold layer; a bit line structure extending in the first direction on the first structure; and a reference bit line structure extending in the first direction on the second structure, wherein the first and second structures respectively comprise a lower electrode, an MTJ structure, an intermediate electrode, and an upper electrode.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail exemplary embodiments thereof referring to the attached drawings, in which:

FIG. 1 is a diagram illustrating an electronic device according to some embodiments;

FIG. 2 is a diagram illustrating a memory region of FIG. 1;

FIG. 3 is a diagram illustrating a memory cell array of FIG. 2;

FIG. 4 is a diagram illustrating the memory cell of FIG. 3;

FIG. 5 is a circuit diagram of a non-volatile memory according to some embodiments;

FIG. 6 is a circuit diagram illustrating a reference resistance control circuit according to some embodiments;

FIG. 7 is a top view of an electronic device according to some embodiments;

FIG. 8 is a diagram illustrating a memory region of FIG. 7;

FIG. 9 is a cross-sectional view of an electronic device taken along A-A′ and D-D′ of FIG. 7;

FIG. 10 is a cross-sectional view of the electronic device taken along B-B′ and E-E′ of FIG. 7;

FIG. 11 is a cross-sectional view of the electronic device taken along C-C′ of FIG. 7;

FIGS. 12, 13, 14, and 15 are cross-sectional views illustrating an electronic device according to some embodiments;

FIGS. 16, 17, and 18 are cross-sectional views illustrating an electronic device according to some embodiments; and

FIGS. 19 and 20 are cross-sectional views illustrating an electronic device according to some embodiments.

### DETAILED DESCRIPTION OF EMBODIMENTS

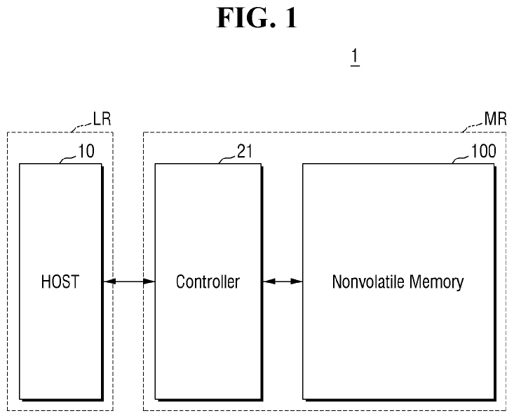

FIG. 1 is a diagram illustrating an electronic device according to some embodiments.

Referring to FIG. 1, an electronic device 1 according to some embodiments may include a logic region LR and a memory region MR. Here, the logic region LR may include a host 10, and the memory region MR may include a controller 21 and a non-volatile memory 100.

In some embodiments, the logic region LR may be electrically connected to memory region MR through an interface. For example, the logic region LR may send signals to the memory region MR to control the memory region MR. Also, for example, the logic region LR may receive signals from the memory region MR and process data included in the signals.

For example, the host 10 may include a central processing unit (CPU), a controller, an application specific integrated circuit (ASIC), or the like. Further, for example, the host 10 may include a memory chip such as a DRAM (Dynamic Random Access Memory), a SRAM (Static RAM), a PRAM (Phase-change RAM), a MRAM (Magneto-resistive RAM), a FeRAM (Ferroelectric RAM), and a RRAM (Resistive RAM).

The memory region MR may include the controller 21 and the non-volatile memory 100. For example, the non-volatile memory 100 may include a magnetic random access memory (MRAM), a phase-change RAM (PRAM), a resistive RAM (RRAM), and the like. However, embodiments of the present disclosure are not limited thereto. The non-volatile memory 100 is not limited to a resistive memory, but may include various non-volatile memories such as an EPROM (Electrically Erasable and Programmable ROM), a flash memory, and a FRAM (Ferroelectric RAM).

The controller 21 and the non-volatile memory 100 may be connected through an interface. The controller 21 may access the non-volatile memory 100. The controller 21 may function as an interface between the host 10 and the non-volatile memory 100. The controller 21 may drive firmware for controlling the non-volatile memory 100.

The interface between the host 10 and the controller 21 may include, for example, various communication standards such as a USB (Universal Serial Bus), a MMC (multimedia card), a PCI (peripheral component wiring), a PCI-E (PCI-express), an ATA (Advanced Technology Attachment), a Serial-ATA, a Parallel-ATA, a SCSI (Small Computer Small Interface), an ESDI (Enhanced Small Disk Interface), an IDE (Integrated Drive Electronics), and Firewire.

The memory region MR may include an embedded MRAM embedded in the electronic device 1. Here, the non-volatile memory 100 of the memory region MR may be embedded inside the electronic device 1. Also, the non-volatile memory 100 may be embedded in the logic region LR. However, the embodiments of the disclosure are not limited thereto.

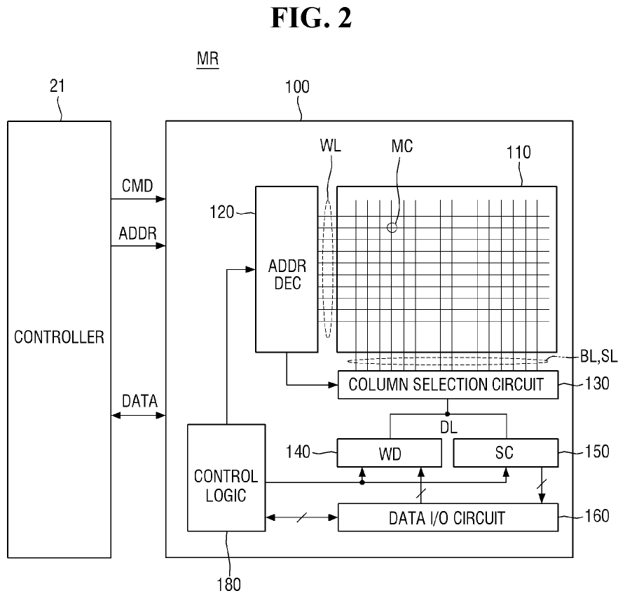

FIG. 2 is a diagram illustrating a memory region of FIG. 1.

Referring to FIGS. 1 and 2, the non-volatile memory 100 may read or write data according to a request of the controller 21. The non-volatile memory 100 may receive command CMD and address ADDR from the controller 21. The command CMD may include read commands, write commands, and the like. For example, when the controller 21 transmits the read command to the non-volatile memory 100, the non-volatile memory 100 provides the controller 21 with data DATA that is read from the memory cell array 110.

The non-volatile memory 100 may include a memory cell array 110, an address decoder circuit 120, a column selection circuit 130, a write driver circuit 140, a sensing circuit 150, a data I/O circuit 160, and a control logic 180. Of course, such a configuration is merely an example, and some components may be omitted or other components may be added, depending on specific implementation purposes.

The memory cell array 110 may include a plurality of memory cells MC for storing the data. Specifically, the memory cell array 110 may include memory cells MC placed (e.g., formed) at points corresponding to a plurality of word lines WL and a plurality of bit lines BL. The memory cell MC may include a variable resistance element in which a value of stored data is distinguished according to the resistance value. For example, the memory cell MC may include a MRAM (Magneto-resistive RAM), a STT-MRAM (Spin Transfer Torque MRAM), a PRAM (Phase-change RAM), a ReRAM (Resistive RAM), and the like. Hereinafter, description will be provided on the assumption that the memory cell MC includes an MRAM.

The address decoder circuit 120 may receive an address ADDR and decode it into a row address and a column address. The address decoder circuit 120 may select one word line WL among a plurality of word lines WL according to the row address. Additionally, in some embodiments, the address decoder circuit 120 may send the column address to the column selection circuit 130. As an example, the address decoder circuit 120 may include components such as the row decoder, the column decoder, the address buffer, and the like.

The column selection circuit 130 is connected to the memory cell array 110 through the bit lines and the source lines, and may be connected to the write driver circuit 140 and the sensing circuit 150. The column selection circuit 130 may operate in response to the control of the control logic 180. The column selection circuit 130 may be configured to receive decoded column addresses from the address decoder circuit 120.

The column selection circuit 130 may also select bit lines and source lines, using the decoded column address. For example, at the time of a write operation, the column selection circuit 130 may connect the selected bit lines BL and source lines SL to data lines DL to connect them to the write driver circuit 140. At the time of read operations, the column selection circuit 130 may connect selected bit lines and source lines to the sensing circuit 150.

The write driver circuit 140 may operate according to the control of control logic 180. The write driver circuit 140 may program the memory cells MC connected to the bit lines BL and source lines SL selected by the column selection circuit 130 and the word lines WL selected by the address decoder circuit 120. The write driver circuit 140 may generate a current or a voltage according to data input from the data I/O circuit 160 and output it to the selected bit lines BL and source lines SL.

The sensing circuit 150 may operate according to the control of the control logic 180. The sensing circuit 150 may include a read circuit that senses the memory cells MC connected to the bit lines BL and source lines SL selected by the column selection circuit 130 and the word line WL selected by the address decoder circuit 120. The read circuit may sense a current flowing through the selected bit lines BL and source lines SL or a voltage applied to the selected bit lines BL and source lines SL to read the memory cell MC. The sensing circuit 150 may output the read data to the data I/O circuit 160.

The data I/O circuit 160 may operate according to the control of the control logic 180. The data I/O circuit 160 may send data, which is input from outside (e.g., from an external device), to the write driver circuit 140 and data, which is input from the sensing circuit 150, to the outside.

The control logic 180 may generally control the operation of non-volatile memory 100. For example, the control logic 180 may control the address decoder circuit 120, the column selection circuit 130, the write driver circuit 140, the sensing circuit 150, the data I/O circuit 160, and the like. Meanwhile, the control logic 180 may operate in response to command input from outside or control signals.

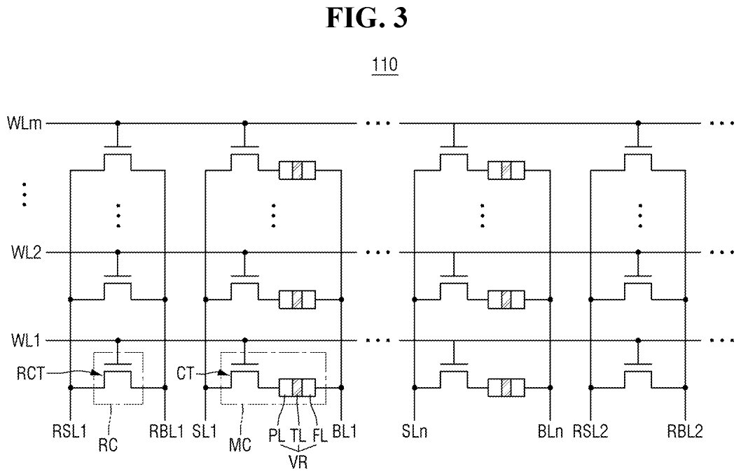

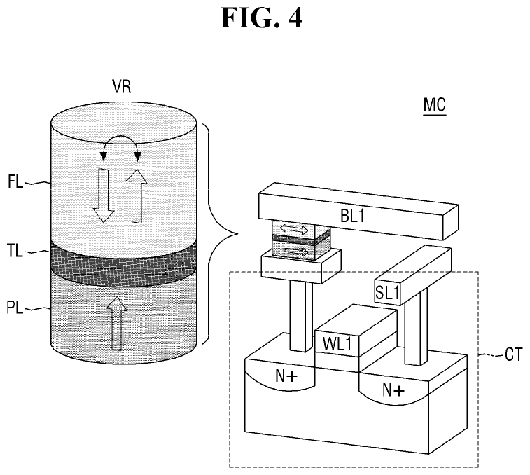

FIG. 3 is a diagram illustrating the memory cell array of FIG. 2. FIG. 4 is a diagram illustrating the memory cell of FIG. 3.

Referring to FIGS. 2 to 4, the memory cell array 110 may include a reference cell RC and a memory cell MC. The reference cell RC and the memory cell MC may be placed along a row direction and a column direction. For example, the reference cell RC may be placed along the first column, the memory cell MC may be placed along a second row to an nth column (n is a natural number), and the reference cell RC may be placed along an nth+1 column. The reference cells RC and the memory cells MC placed along the first column to the nth+1 column may be repeatedly placed. The terms “first,” “second,” “third,” “primary,” “secondary,” etc. are used herein merely to distinguish one element from another.

The reference cell RC may include a reference cell transistor RCT, and the memory cell MC may include a cell transistor CT and a variable resistance element VR.

A gate of the reference cell transistor RCT and a gate of the cell transistor CT may be connected to word lines WL1 to WLm (m is a natural number). Gates of the reference cell transistors RCT and the cell transistors CT placed in the row direction may be commonly connected to one word line. Voltages of the word lines WL1 to WLm may be controlled through the address decoder circuit 120 by the control of the control logic 180.

One end (e.g., source or drain) of the reference cell transistor RCT may be connected to the reference source lines RSL1 and RSL2, and the other end thereof may be connected to the reference bit lines RBL1 and RBL2. One end of the reference cell transistors RCT placed in the column direction may be commonly connected to one reference source line, and the other end thereof may be commonly connected to one reference bit line. One end (e.g., source or drain) of the cell transistor CT may be connected to the source lines SL1 to SLn, and the other end thereof may be connected to the variable resistance element VR. The variable resistance element VR may be connected to the bit lines BL1 to BLn. The memory cells MC placed in the column direction may be commonly connected to one source line and one bit line.

The variable resistance element VR may include a pinned layer PL, a tunnel layer TL, and a free layer FL. A magnetization direction of the pinned layer PL is fixed, and the magnetization direction of the free layer FL may be the same as or opposite to the magnetization direction of the pinned layer PL depending on the conditions. The variable resistance element MTJ may further include an anti-ferromagnetic layer to fix the magnetization direction of the pinned layer PL.

For example, the magnetization direction of the free layer FL and the magnetization direction of the pinned layer PL of the variable resistance element VR may be placed parallel (p). In this case, the variable resistance element VR has a low resistance value. In this case, the data may be discriminated, for example, as “0”. The magnetization direction of the free layer FL of the variable resistance element VR may be placed anti-parallel (ap) to the magnetization direction of the pinned layer PL. In this case, variable resistance element VR has a high resistance value. In this case, the data may be discriminated, for example, as “1”.

Meanwhile, although FIG. 4 shows the free layer FL and the pinned layer PL of the variable resistance element VR as horizontal magnetic elements, the embodiments are not limited thereto. In some other embodiments, the free layer FL and the pinned layer PL may be provided in the form of perpendicular magnetic elements.

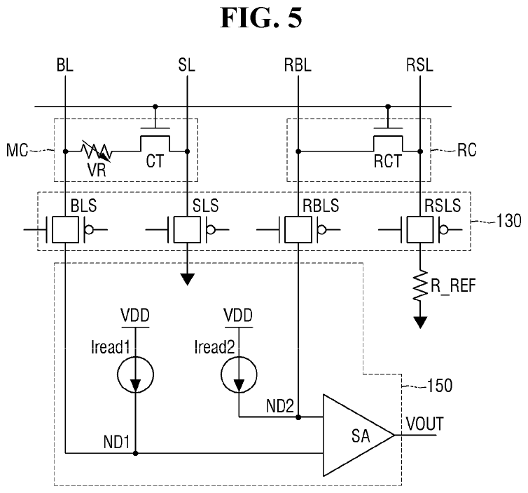

FIG. 5 is a circuit diagram of a non-volatile memory according to some embodiments. For convenience of explanation, the description will be provided by the use of one reference cell RC and one memory cell MC.

Referring to FIG. 5, the column selection circuit 130 includes column selection elements BLS, SLS, RBLS and RSLS, and the sensing circuit 150 may include a sense amplifier SA and first and second current sources Iread1 and Iread2. A first current source that provides a first current Iread1 is connected to the first node ND1 of the sense amplifier SA, and a second current source that provides a second current Iread2 may be connected to the second node ND2 of the sense amplifier SA.

The bit line BL, the source line SL, the reference bit line RBL and the reference source line RSL may be connected to the column selection circuit 130. After the column select elements BLS and SLS are turned on, the first current Iread1 may be applied to the memory cell MC connected to the selected word line WL among the memory cells MC connected to the bit line BL and the source line SL. After the column selection elements RBLS and RSLS are turned on, the second current Iread2 may be applied to the reference cell RC connected to the selected word line WL among the reference cells RC connected to the reference bit line RBL and the reference source line RSL. A second node ND2 and a reference resistor R_REF may be connected through a reference wiring structure which will be described later.

The sense amplifier SA may sense a voltage difference between the first node ND1 and the second node ND2 and amplify the difference. The amplified voltage difference may be output as an output voltage VOUT, and may be used to discriminate the data read from the memory cell MC.

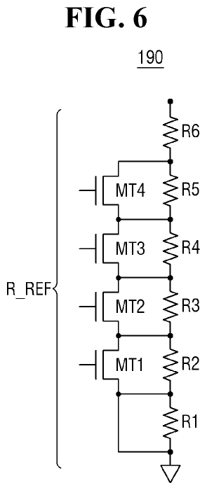

FIG. 6 is a circuit diagram illustrating a reference resistance control circuit according to some embodiments.

Referring to FIG. 6, a reference resistance control circuit 190 may include a plurality of transistors MT1, MT2, MT3, and MT4 and a plurality of resistors R1, R2, R3, R4, R5, and R6. The reference resistance control circuit 190 may be connected to the reference cell RC. The plurality of resistors R1, R2, R3, R4, R5, and R6 are connected in series to the reference cell RC, and each of the first to fourth transistors MT1, MT2, MT3, and MT4 may be connected in parallel to each of the second to fifth resistors R2, R3, R4 and R5. Each of the first to fourth transistors MT1, MT2, MT3, and MT4 may be controlled by a respective trimming signal. Although FIG. 6 shows that the reference resistance control circuit 190 includes the four transistors MT1, MT2, MT3, and MT4 and the six resistors R1, R2, R3, R4, R5, and R6, the embodiments are not limited thereto.

The reference resistor control circuit 190 generates a reference resistor R_REF with resistors R1, R2, R3, R4, R5, and R6 selectively shorted by the trimming signal. The trimming signal may be provided from the control logic 180 of FIG. 2. The reference resistor R_REF may be connected to the reference bit line RBL and provided to the second node ND2 of the sense amplifier SA.

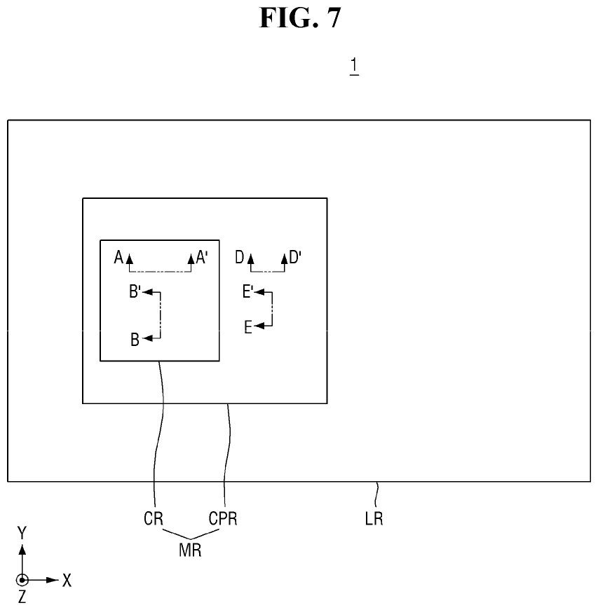

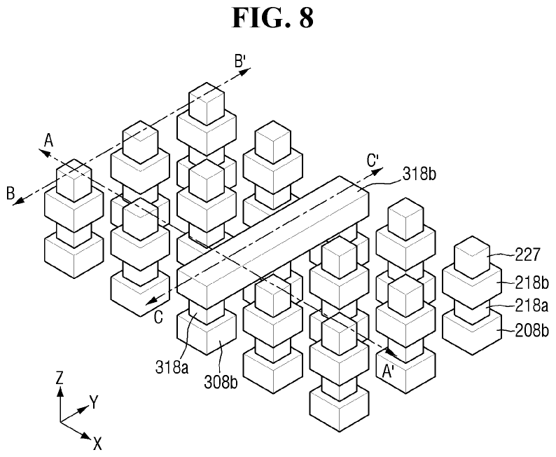

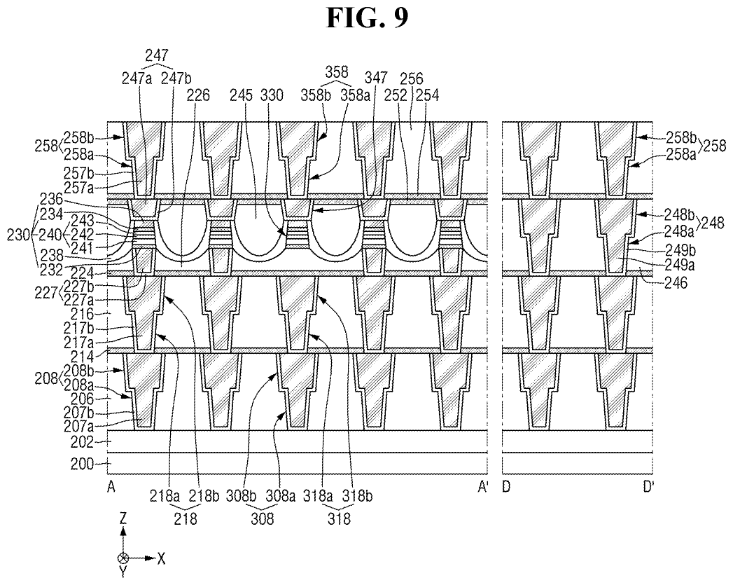

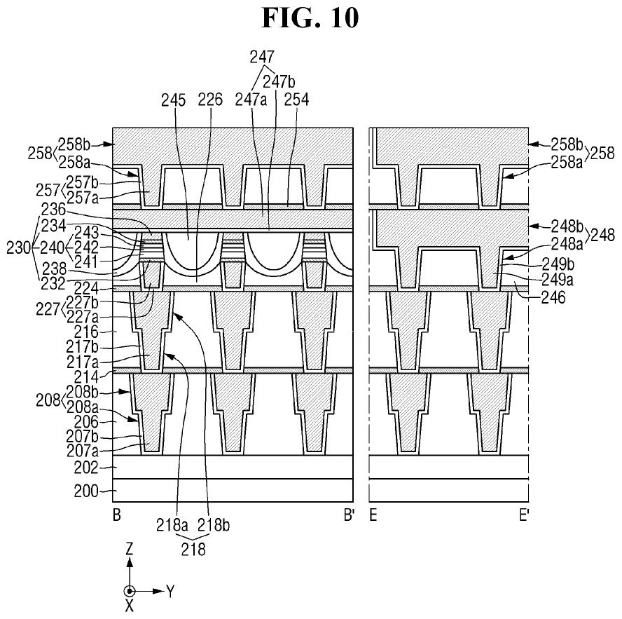

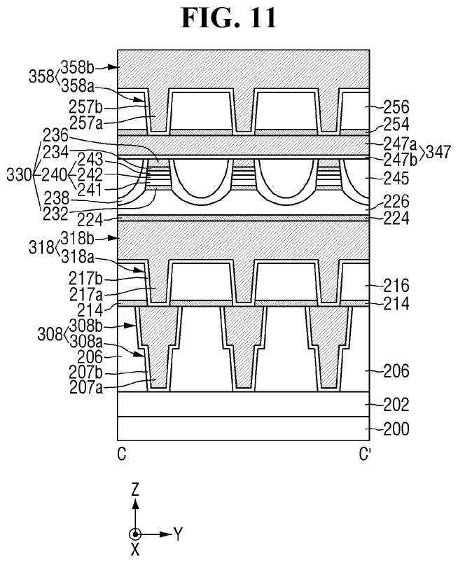

FIG. 7 is a top view of an electronic device according to some embodiments. FIG. 8 is a diagram illustrating memory region of FIG. 7. FIG. 9 is a cross-sectional view of the electronic device taken along A-A′ and D-D′ of FIG. 7. FIG. 10 is a cross-sectional view of the electronic device taken along B-B′ and E-E′ of FIG. 7. FIG. 11 is a cross-sectional view of the electronic device taken along C-C′ of FIG. 8. For reference, FIG. 8 is a diagram showing some wiring structures and a lower electrode contact. A-A′, B-B′ and C-C′ of FIG. 8 correspond to A-A′, B-B′ and C-C′ of FIG. 7, respectively.

Referring to FIG. 7, the electronic device 1 may include a memory region MR and a logic region LR. As described referring to FIGS. 1 to 6, the memory region MR may include the controller 21 and the non-volatile memory 100, and the logic region LR may include the host 10. Here, the memory region MR may be embedded in the electronic device 1, and in this case, the memory region MR may be an embedded MRAM (eMRAM).

The memory region MR and the logic region LR may be embedded in the electronic device 1. Referring to FIG. 7, although the memory region MR may be surrounded by the logic region LR, the embodiments of the present disclosure are not limited thereto. The memory region MR may include a cell region CR and a core peri region CPR. The cell region CR may be surrounded by the core peri region CPR, but embodiments of the present disclosure are not limited thereto. The cell region CR may correspond to the memory cell array 110 of FIGS. 2 and 3, and the core peri region CPR may correspond to the address decoder circuit 120, the column selection circuit 130, the write driver circuit 140, the sensing circuit 150, the data I/O circuit 160, the control logic 180, and the like. That is, the cell region CR may include a memory cell array 110 including the memory cell MC, and the core peri region CPR may include a circuit region around the memory cell array 110. Here, although the cell region CR is shown as not overlapping by the core peri region CPR, the embodiments of the disclosure are not limited thereto. For example, the core peri region CPR may overlap the cell region CR, e.g., in the Z-direction.

Referring to FIGS. 7 to 11, the electronic device 1 may include a substrate 200, a lower insulating layer 202, first and second upper insulating layers 206 and 216, first wiring structures 208 and 308, second wiring structures 218 and 318, a second upper insulating layer 216, first to fourth mold layers 226, 245, 246 and 256, third wiring structures 247 and 347, a fourth wiring structure 248, and fifth wiring structures 258 and 358.

The electronic device 1 may include a substrate 200 including the cell region CR and the core peri region CPR. The substrate 200 may extend flat or may be substantially planar along the first direction X and the second direction Y. The substrate 200 may include silicon, germanium, silicon-germanium, or group III-V compounds such as GaP, GaAs and GaSb. In some embodiments, the substrate 200 may be a silicon-on-insulator (SOI) substrate or a germanium-on-insulator (GOI) substrate.

A circuit pattern formed on the substrate 200 of the cell region CR may include selection elements (e.g., the cell transistors CT of FIG. 3) that constitute the memory cells MC, and the circuit pattern formed on the substrate 200 of the core peri region CPR may include logic transistors corresponding to the logic circuit or the peripheral circuit.

The lower insulating layer 202 may cover the substrate 200. Specifically, the lower insulating layer 202 may cover circuit patterns on the substrate 200. The lower insulating layer 202 may extend in the first direction X and the second direction Y to cover the substrate 200 corresponding to the cell region CR and the core peri region CPR. The first lower wirings may be formed inside the lower insulating layer 202.

The lower insulating layer 202 may include a plurality of interlayer insulating layers. The first lower wirings may be formed inside a plurality of interlayer insulating layers. The lower insulating layer 202 may include silicon oxide. The first lower wiring formed in the lower insulating layer 202 may include contact plugs, conductive patterns, and the like. Also, the first lower wiring formed in the lower insulating layer 202 may include polysilicon, metal, or the like. Although the thicknesses of the substrate 200 and the lower insulating layer 202 in the third direction Z are shown to be smaller than the thicknesses of the other layers, the embodiments of the disclosure are not limited thereto. That is, the substrate 200 and the lower insulating layer 202 may include a plurality of layers and may have a thickness greater than other layers.

A first upper insulating layer 206 may be formed on the lower insulating layer 202 corresponding to the cell region CR and the core peri region CPR. The first wiring structures 208 and 308 may be placed in the first upper insulating layer 206. The first wiring structures 208 and 308 may be aligned in or along the first direction X and the second direction Y. The upper surface of the first upper insulating layer 206 and the upper surfaces of the first wiring structures 208 and 308 may be located on the substantially same plane, i.e., substantially coplanar.

The first wiring structures 208 and 308 may be aligned in the column direction, and may be aligned in the row direction inside one column direction. The column direction may refer to the second direction Y, and the row direction may refer to the first direction X. The first wiring structures 208 and 308 may include a first-1 (also referred to herein as first primary) wiring structure 208 and a first-2 (also referred to herein as first secondary) wiring structure 308 placed in different columns from each other. The first-2 wiring structures 308 may be placed between the first-1 wiring structures 208 placed in different columns from each other. The first-1 wiring structure 208 and the first-2 wiring structure 308 may be spaced apart in the first direction X. The first-1 wiring structure 208 may be formed in the first upper insulating layer 206 on the cell region CR and the core peri region CPR, and may be connected to the lower insulating layer 202 and the substrate 200.

The first-1 wiring structure 208 may include a first-1 via 208a and a first-1 wiring 208b on the first-1 via 208a, and the first-2 wiring structure 308 may include a first-2 via 308a and a first-2 wiring 308b on the first-2 via 308a. The first-1 and first-2 vias 208a and 308a may have a cylindrical shape. That is, the first-1 and first-2 vias 208a and 308a may have widths in the first direction X and the second direction Y, respectively. The first-1 and first-2 wirings 208b and 308b may have a cylindrical shape. The first wiring structures 208 and 308 may have, for example, an island shape. The widths of the first-1 and first-2 wirings 208b and 308b in the first direction X and the second direction Y may be larger than the widths of the first-1 and first-2 vias 208a and 308a in the first direction X and the second direction Y.

The first wiring structure 208 and 308 may include a first barrier pattern 207b and a first conductive pattern 207a on the first barrier pattern 207b. The first barrier pattern 207b may be formed to surround the side surface and bottom surfaces of the first conductive pattern 207a. The first barrier pattern 207b may include, for example, metal nitrides such as tungsten nitride, tantalum nitride and titanium nitride, and/or metals such as tantalum and titanium. The first conductive pattern 207a may include, for example, copper.

A first etch stop film 214 may be placed on the first upper insulating layer 206 of the cell region CR and the core peri region CPR. The first etch stop film 214 may include silicon nitride, silicon carbonitride, or the like.

A second upper insulating layer 216 may be placed on the first etch stop film 214 of the cell region CR and the core peri region CPR. Second wiring structures 218 and 318 may be placed inside the second upper insulating layer 216. A upper surface of the second upper insulating layer 216 and upper surfaces of the second wiring structures 218 and 318 may be located on the substantially same plane. The second wiring structures 218 and 318 may include a second-1 (also referred to herein as a second primary) wiring structure 218 on the first-1 wiring structure 208, and a second-2 (also referred to herein as a second secondary) wiring structure 318 on the first-2 wiring structure 308. The second-1 wiring structure 218 may be placed on the first-1 wiring structure 208 on the cell region CR and the core peri region CPR.

Each of the second-1 and second-2 wiring structures 218 and 318 penetrate the first etch stop film 214, and may be electrically connected to each of the first-1 and first-2 wiring structures 208 and 308. The second-1 and second-2 wiring structures 218 and 318 may come into contact (e.g., direct contact) with the first-1 and first-2 wiring structures 208 and 308. As used herein, when elements are in direct contact, no intervening elements may be present.

The second-1 wiring structure 218 may include a second-1 via 218a and a second-1 wiring 218b on the second-1 via 218a, and the second-2 wiring structure 318 may include a second-2 via 318a and a second-2 wiring 318b on the second-2 via 318a. The second-1 wiring structures 218 may be placed on the first-1 wiring structures 208, respectively. The second-1 wiring structure 218 may have, for example, an island shape. The width of the second-1 wiring 218b in the first direction X and the second direction Y may be larger than the width of the second-1 via 218a in the first direction X and the second direction Y.

The second-2 wiring structure 318 may extend along the second direction Y. The second-2 wiring structure 318 may include a second-2 via 318a placed along the second direction Y, and one second-2 wiring 318b extending along the second direction Y on the second-2 via 318a. The second-2 wiring 318b may have, for example, a line shape. The width of the second-2 wiring 308b in the first direction X may be greater than the width of the second-2 via 308a in the first direction X.

The second wiring structures 218 and 318 may include a second barrier pattern 217b and a second conductive pattern 217a on the second barrier pattern 217b. The second barrier pattern 217b may be formed to surround the side surface and bottom surface of the second conductive pattern 217a. The second barrier pattern 217b may include, for example, metal nitrides such as tungsten nitride, tantalum nitride and titanium nitride, and/or metals such as tantalum and titanium. The second conductive pattern 217a may include, for example, copper.

A second etch stop film 224 may be placed on the second upper insulating layer 216 of the cell region CR and the core peri region CPR. The second etch stop film 224 may include silicon nitride, silicon carbonitride, or the like. A first mold layer 226 may be placed on the second etch stop film 224 on the cell region CR. An upper surface of the first mold layer 226 may be recessed toward the second upper insulating layer 216. The thickness of the first mold layer 226 may decrease toward the first and second structures 230 and 330, and may increase away from the first and second structures 230 and 330, or vice versa.

A lower electrode contact 227 may be placed in the first mold layer 226. The lower electrode contact 227 may be located in the cell region CR but may not be located in the core peri region CPR. The lower electrode contact 227 may be placed on the second-1 wiring structure 218 but may not be placed on the second-2 wiring structure 318. The lower electrode contact 227 penetrates the second etching stop film 224 on the cell region CR, may be electrically connected to the second-1 wiring structure 218, and may not be electrically connected to the second-2 wiring structure 318.

The lower electrode contact 227 may include a barrier pattern 227a and a conductive pattern 227b on the barrier pattern 227a. The barrier pattern 227a may include metal nitrides such as tungsten nitride, tantalum nitride and titanium nitride, and/or metals such as tantalum and titanium, and the conductive pattern 227b may include a conductive material such as copper.

The first structure 230 may be placed on the second-1 wiring structure 218 on the cell region CR, and the second structure 330 may be placed on the second-2 wiring structure 318. The first and second structures 230 and 330 may be placed in the cell region CR and not placed in the core peri region CPR. The first structure 230 may be placed on the lower electrode contact 227. The first structure 230 may come into contact with the lower electrode contact 227. The second structure 330 may be spaced apart from the second-2 wiring structure 318 by the first mold layer 226, e.g., in the Z-direction.

The first and second structures 230 and 330 may include a lower electrode 232, an MTJ structure 240 on the lower electrode 232, an intermediate electrode 234 on the MTJ structure 240, and an upper electrode 236 on the intermediate electrode 234, respectively. The first and second structures 230 and 330 may have sloped side walls. Widths of the first and second structures 230 and 330 may decrease as they extend away from the second upper insulating layer 216.

The lower electrode 232 may include metals such as titanium and tantalum or metal nitrides such as titanium nitride and tantalum nitride.

The MTJ structure 240 may include a first magnetic pattern 241, a tunnel barrier pattern 242, a second magnetic pattern 243, and the like.

The first magnetic pattern 241 may be a pinned layer having a fixed magnetization direction. For example, the first magnetic pattern 241 may include a pinned pattern, a lower ferromagnetic pattern, an antiferromagnetic coupling spacer pattern, and an upper ferromagnetic pattern. For example, the first magnetic pattern 232a may include manganese iron (FeMn), manganese iridium (IrMn), manganese platinum (PtMn), manganese oxide (MnO), manganese sulfide (MnS), manganese tellurium (MnTe), manganese fluoride (MnF₂), iron fluoride (FeF₂), iron chloride (FeCl₂), iron oxide (FeO), cobalt chloride (CoCl₂), cobalt oxide (CoO), nickel chloride (NiCl₂), nickel oxide (NiO), chromium (Cr), and the like. The upper and lower ferromagnetic patterns corresponding to the first magnetic pattern 241 may include, for example, ferromagnetic materials including at least one of iron (Fe), nickel (Ni) or cobalt (Co). The antiferromagnetic coupling spacer pattern corresponding to the first magnetic pattern 241 may include, for example, at least one of ruthenium (Ru), iridium (Ir), or rhodium (Rh).

The second magnetic pattern 243 may be a free layer having a variable magnetization direction. For example, the second magnetic pattern 243 may include ferromagnetic materials such as iron (Fe), cobalt (Co), nickel (Ni), chromium (Cr), and platinum (Pt). The second magnetic pattern 243 may further include boron (B) or silicon (Si). In addition, the second magnetic pattern 243 may include composite materials such as CoFe, NiFe, FeCr, CoFeNi, PtCr, CoCrPt, CoFeB, NiFeSiB, and CoFeSiB.

The tunnel barrier pattern 242 may be placed between the first and second magnetic patterns 241 and 243. Therefore, the first and second magnetic patterns 241 and 243 may not be in direct contact with each other. The tunnel barrier pattern 242 may include metal oxide having insulating properties. For example, the tunnel barrier pattern 242 may include magnesium oxide (MgOx) or aluminum oxide (AlOx).

The intermediate electrode 234 may include at least one of a metal such as titanium and tantalum, or a metal nitride such as titanium nitride and tantalum nitride.

The upper electrode 236 may include tungsten, copper, platinum, nickel, silver, gold, and the like.

A capping film 238 may be formed on side walls of the first mold layer 226 and the first and second structures 230 and 330 of the cell region CR. The capping film 238 may extend along the upper surface of the first mold layer 226 and side walls of the first and second structures 230 and 330 of the cell region CR. The upper surface of the capping film 238 may be recessed toward the second upper insulating layer 216, like the upper surface of the first mold layer 226. The capping film 238 may protect the first and second structures 230 and 330. The capping film 238 may include silicon nitride or silicon oxynitride.

A second mold layer 245 may be placed on the capping film 238. The second mold layer 245 may fill the space between the first and second structures 230 and 330. The second mold layer 245 may wrap the side walls of the first and second structures 230 and 330. The second mold layer 245 may include an oxide such as silicon oxide.

Third wiring structures 247 and 347 may be placed inside the second mold layer 245. The third wiring structures 247 and 347 may include a third-1 (also referred to herein as a third primary) wiring structure 247 placed on the first structure 230, and a third-2 (also referred to herein as a third secondary) wiring structure 347 placed on the second structure 330. The third-1 and third-2 wiring structures 247 and 347 may be electrically connected to the first and second structures 230 and 330, respectively. The third-1 and third-2 wiring structures 247 and 347 may come into contact with the first and second structures 230 and 330, respectively.

The third wiring structures 247 and 347 may extend along the second direction Y. The third wiring structures 247 and 347 may have, for example, a line shape. The third wiring structures 247 and 347 may include a third barrier pattern 247b, and a third conductive pattern 247a on the third barrier pattern 247b. The third barrier pattern 247b may be formed to surround the side surface and the bottom surface of the third conductive pattern 247a. The third barrier pattern 247b may include metal nitrides such as tungsten nitride, tantalum nitride and titanium nitride, and/or metals such as tantalum and titanium, and the third conductive pattern 247a may include a conductive material such as copper.

The first mold layer 226, the capping film 238, the second mold layer 245 and the third etch stop film 252 on the core peri region CPR may be replaced with a third mold layer 246. A upper surface of the third mold layer 246 on the core peri region CPR may be placed on the same plane as an upper surface of the third etch stop film 252 on the cell region CR.

A third mold layer 246 may be placed on the second etch stop film 224 on the core peri region CPR. The third mold layer 246 may not be placed on the cell region CR. The third mold layer 246 may include oxide. For example, the third mold layer 246 may include an oxide such as ULK (ultra low-k). However, the second mold layer 245 may include HDP-CVD (high density plasma-chemical vapor deposition) oxide. That is, the second and third mold layers 245 and 246 may include different materials from each other.

A fourth wiring structure 248 may be placed inside the third mold layer 246. The fourth wiring structure 248 may be placed on the second wiring structure 218 on the core peri region CPR. The fourth wiring structure 248 penetrates the second etch stop film 224 on the core peri region CPR, and may be electrically connected to the second wiring structure 218 on the core peri region CPR. The fourth wiring structure 248 on the core peri region CPR may come into contact with the second wiring structure 218 on the core peri region CPR.

The fourth wiring structure 248 may extend along the second direction Y. The fourth wiring structure 248 may include a fourth via 248a and a fourth wiring 248b on the fourth via 248a. The fourth via 248a may be placed along the second direction Y. The width of the fourth wiring 248b in the first direction X may be greater than the width of the fourth via 248a in the first direction X. The fourth wiring 248b may be formed by the same process as the third wiring structures 247 and 347.

The fourth wiring structure 248 may include a fourth barrier pattern 249b and a fourth conductive pattern 249a on the fourth barrier pattern 249b. The fourth barrier pattern 249b may be formed to surround the side surface and bottom surface of the fourth conductive pattern 249a.

The third etch stop film 252 may be formed on the second mold layer 245 of the cell region CR. The third etch stop film 252 may not be formed in the core peri region CPR. The third etch stop film 252 may include silicon nitride, silicon carbonitride, or the like. The fourth etch stop film 254 may be placed on the third etch stop film 252 of the cell region CR and the third mold layer 246 of the core peri region CPR. The fourth etch stop film 254 may include silicon nitride, silicon carbonitride, or the like.

The fourth mold layer 256 is placed on the fourth etch stop film 254 on the cell region CR and the core peri region CPR. The fifth wiring structures 258 and 358 may be placed inside the fourth mold layer 256. The fifth wiring structures 258 and 358 may include a fifth-1 (also referred to herein as a fifth primary) wiring structure 258 placed on the third-1 wiring structure 247 and the fourth wiring structure 248, and a fifth-2 (also referred to herein as a fifth secondary) wiring structure 358 placed on the third-2 wiring structure 347. The third wiring structures 247 and 347 may penetrate the third etch stop film 252. The fifth-1 wiring structure 258 penetrates the fourth etch stop film 254, and may be electrically connected to the third-1 wiring structure 247 and the fourth wiring structure 248. The fifth-2 wiring structure 358 penetrates the fourth etch stop film 254, and may be electrically connected to the third-2 wiring structure 347. The fifth-1 wiring structure 258 may come into contact with the third-1 wiring structure 247 and the fourth wiring structure 248, and the fifth-2 wiring structure 358 may come into contact with the third-2 wiring structure 347.

The fifth wiring structures 258 and 358 may extend along the second direction Y. The fifth-1 wiring structure 258 may include a fifth-1 via 258a placed along the second direction Y, and a fifth-1 wiring 258b extending along the second direction Y on the fifth-1 via 258a. The fifth-1 wiring 258b may have, for example, a line shape. The fifth-2 wiring structure 358 may include a fifth-2 via 358a placed along the second direction Y, and a fifth-2 wiring 358b extending along the second direction Y on the fifth-2 via 358a. The fifth-2 wiring 358b may have, for example, a line shape. The widths of the fifth-1 and fifth-2 wirings 258b and 358b in the first direction X may be greater than the widths of the fifth-1 and fifth-2 vias 258a and 358a in the first direction X.

The fifth wiring structures 258 and 358 may include a fifth barrier pattern 257b and a second conductive pattern 257a. The fifth barrier pattern 257b may be formed to surround side walls and a bottom surface of the second conductive pattern 257a.

Referring to FIGS. 5 to 11, the fifth-1 wiring 258b of the fifth-1 wiring structure 258 may correspond to the bit line BL, and the fifth-2 wiring 358b of the fifth-2 wiring structure 358 may correspond to the reference bit line RBL. The fifth-1 wiring 258b may be electrically connected to the core peri region CPR. The fifth-1 wiring 258b may be electrically connected to the first node ND1 of the sense amplifier SA. The fifth-2 wiring 358b may not be electrically connected to the core peri region CPR. That is, the MTJ structure 240 of the second structure 550 may be a dummy or non-functional structure in which no data is stored.

The second node ND2 of the sense amplifier SA and the reference resistor R_REF may be electrically connected through the second-2 wiring 318b of the second-2 wiring structure 318. The second-2 wiring structure 318 may be the reference wiring structure of FIG. 5. The second-2 wiring structure 318 may be repeatedly placed as described using FIGS. 3 and 5.

The second-2 wiring structure 318 may have an island shape extending in the second direction Y, unlike the island-shaped second-1 wiring structure 218. When the lower electrode contact 227 is formed on the second-1 and second-2 wiring structures 218 and 318, one lower electrode contact 227 is formed on the single second-1 wiring structure 218, but a plurality of lower electrode contacts 227 are formed on the second-2 wiring structure 318. Therefore, a void or the like may be formed in the second-2 wiring structure 318 in the process of forming the lower electrode contact 227. This may cause problems when measuring the reference resistance R_REF.

However, in the electronic device 1 according to some embodiments, the lower electrode contact 227 is not placed on the second-2 wiring structure (e.g., the reference wiring structure) 318. Therefore, the possibility that void or the like is formed in the second-2 wiring structure 318 may remarkably decrease, and the reliability of the reference resistor R_REF may be improved.

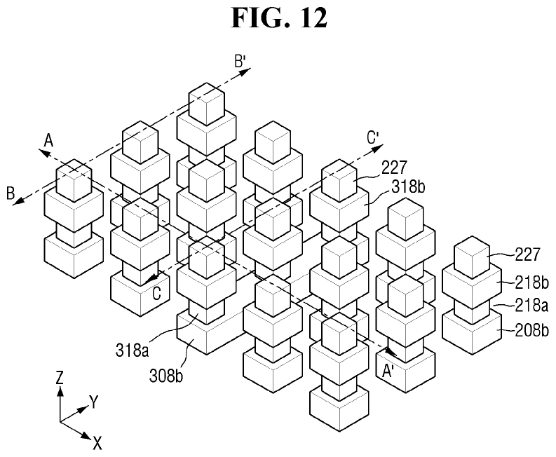

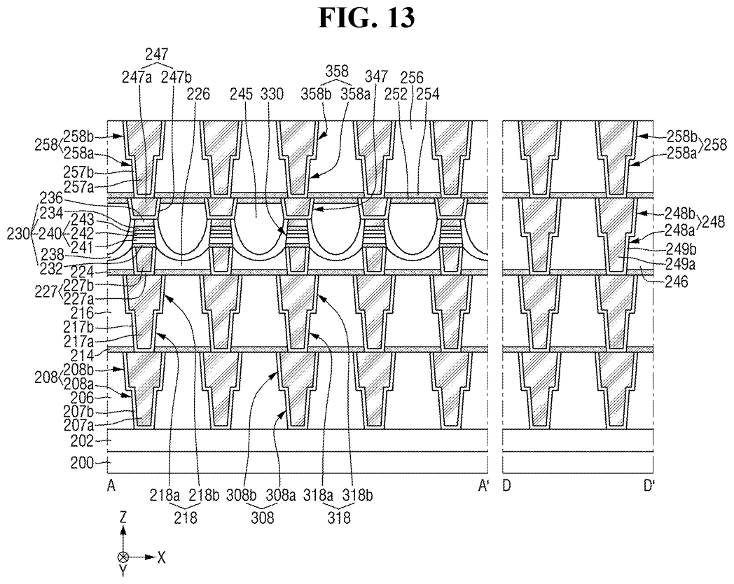

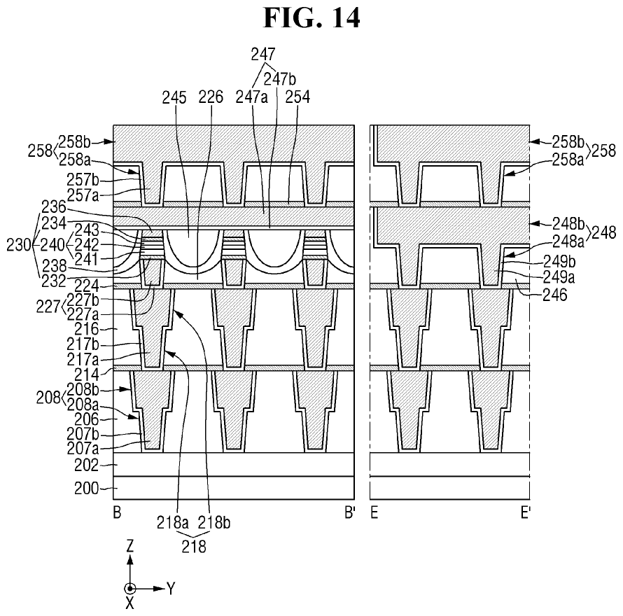

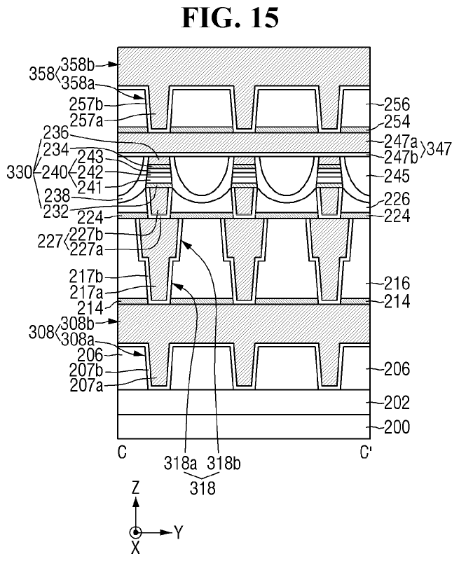

FIGS. 12 to 15 are cross-sectional views illustrating an electronic device according to some embodiments. For reference, FIG. 13 is a cross-sectional view of the electronic device taken along A-A′ and D-D′ of FIG. 7, FIG. 14 is a cross-sectional view of the electronic device taken along B-B′ and E-E′ of FIG. 7, and FIG. 15 is a cross-sectional view of the electronic device taken along C-C′ of FIG. 12. For reference, FIG. 12 is a diagram showing some wiring structures and lower electrode contacts. A-A′, B-B′ and C-C′ of FIG. 12 correspond to A-A′, B-B′ and C-C′ of FIG. 7, respectively. For convenience of explanation, repeated parts of contents explained using FIGS. 1 to 11 will be briefly explained or omitted.

Referring to FIGS. 7 and 12 to 15, in the electronic device 1 according to some embodiments, the first-2 wiring structure 308 may extend along the second direction Y. The first-2 wiring structure 308 may include a first-2 via 308a placed along the second direction Y, and a first-2 wiring 308b extending along the second direction Y on the first-2 via 308a. The first-2 wiring 308b may have, for example, a line shape. The first-1 wiring structure 208 may have, for example, an island shape. The width of the first-2 wiring 308b in the first direction X may be greater than the width of the first-2 via 308a in the first direction X.

The second-2 wiring structure 318 may include a second-2 via 318a on the first-2 wiring structure 308, and a second-2 wiring 318b on the second-2 via 318a. The second-2 wiring structure 318 may have, for example, an island shape. The widths of the second-2 via 318a in the first direction X and the second direction Y may be greater than the widths of the second-2 via 308a in the first direction X and the second direction Y.

The lower electrode contact 227 may be placed on the second-1 wiring structure 218 and the second-2 wiring structure 318. The lower electrode contact 227 penetrates the second etch stop film 224 on the cell region CR, and may be electrically connected to the second-1 and second-2 wiring structure 218 and 318. Since the lower electrode contact 227 is formed on the second-1 and second-2 wiring structures 218 and 318 inside the memory cell array, the lower electrode contact 227 may be placed uniformly.

A second structure 330 may be placed on the lower electrode contact 227. The second structure 330 may come into contact with the lower electrode contact 227. The second structure 330 may be electrically connected to the second-2 wiring structure 318 through the lower electrode contact 227.

Referring to FIGS. 5 and 12 to 15, the fifth-1 wiring 258b of the fifth-1 wiring structure 258 may correspond to the bit line BL, and the fifth-2 wiring 358b of the fifth-2 wiring structure 358 may correspond to the reference bit line RBL. The second-2 wiring structure 318 may be repeatedly placed as described using FIGS. 3 and 5.

The fifth-1 wiring 258b may be electrically connected to the core peri region CPR. The fifth-1 wiring 258b may be electrically connected to the first node ND1 of the sense amplifier SA. The fifth-2 wiring 358b may not be electrically connected to the core peri region CPR. That is, the MTJ structure 240 of the second structure 550 may be a dummy or non-functional structure in which no data is stored.

The second node ND2 of the sense amplifier SA and the reference resistor R_REF may be electrically connected through the first-2 wiring 308b of the first-2 wiring structure 308. The first-2 wiring 308b of the first-2 wiring structure 308 may be the reference wiring structure of FIG. 5. The first-2 wiring structure 308 may be repeatedly placed as described using FIGS. 3 to 5.

The first-2 wiring structure 308 may have an island shape extending in the second direction Y, unlike the island-shaped first-1 wiring structure 208. Since the first-2 wiring structure 308 is formed inside the first upper insulating layer 206, no voids or the like are formed in the process of forming the lower electrode contact 227. Therefore, the reliability of the reference resistor R_REF can be improved.

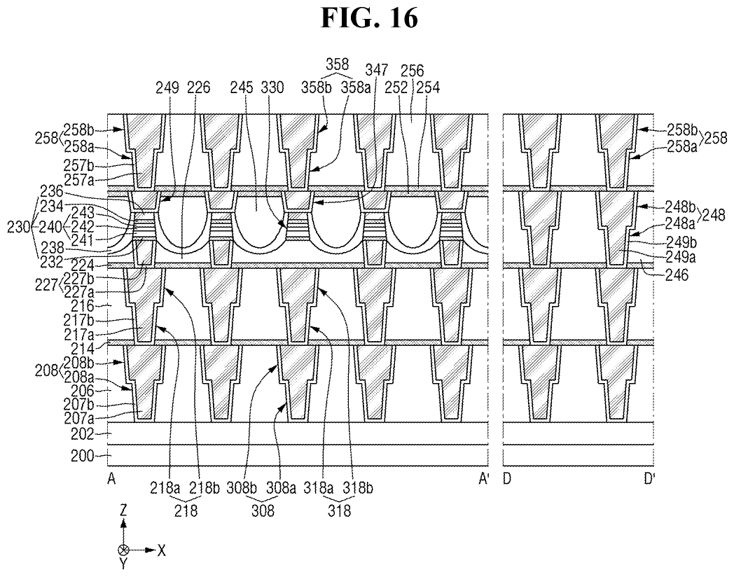

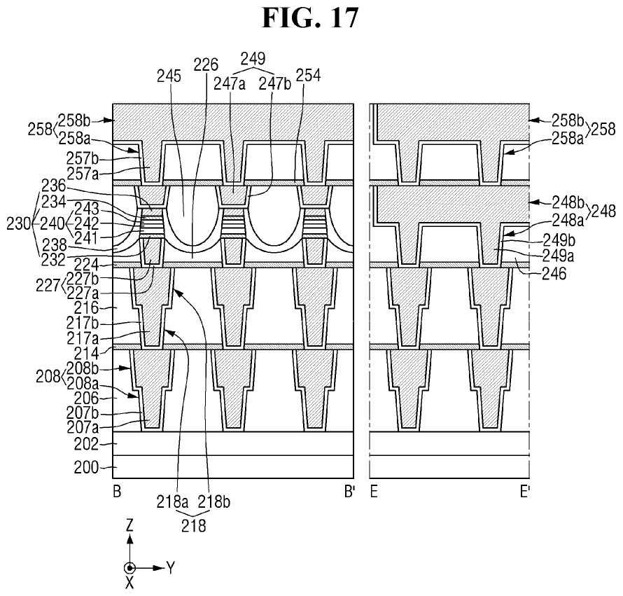

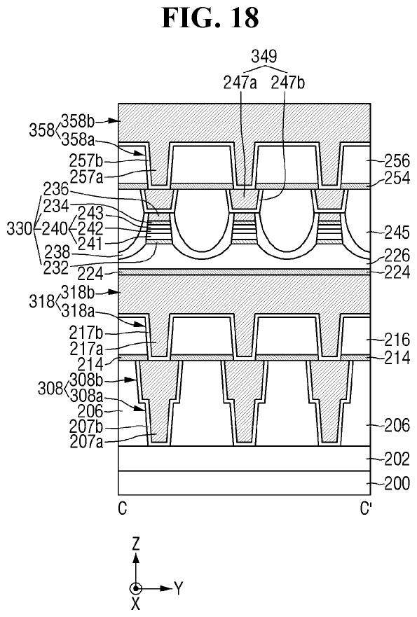

FIGS. 16 to 18 are cross-sectional views illustrating an electronic device according to some embodiments. For reference, FIG. 16 is a cross-sectional view of the electronic device taken along A-A′ and D-D′ of FIG. 7, FIG. 17 is a cross-sectional view of the electronic device taken along B-B′ and E-E′ of FIG. 7, and FIG. 18 is a cross-sectional view of the electronic device taken along C-C′ of FIG. 8. For convenience of explanation, repeated parts of contents explained using FIGS. 1 to 11 will be briefly explained or omitted.

Referring to FIGS. 7 and 16 to 18, in the electronic device 1 according to some embodiments, the contact structures 249 and 349 may be placed in the second mold layer 245. The contact structures 249 and 349 may include a first contact structure 249 placed on the first structure 230 and a second contact structure 349 placed on the second structure 330. The first and second contact structures 249 and 349 may be electrically connected to the first and second structures 230 and 330, respectively. The first and second contact structures 249 and 349 may come into contact with the first and second structures 230 and 330, respectively.

The contact structures 249 and 349 may have a via shape, unlike the third wiring structures 247 and 347 extending in the second direction Y of FIGS. 1 to 11. The contact structures 249 and 349 may have, for example, and island shape.

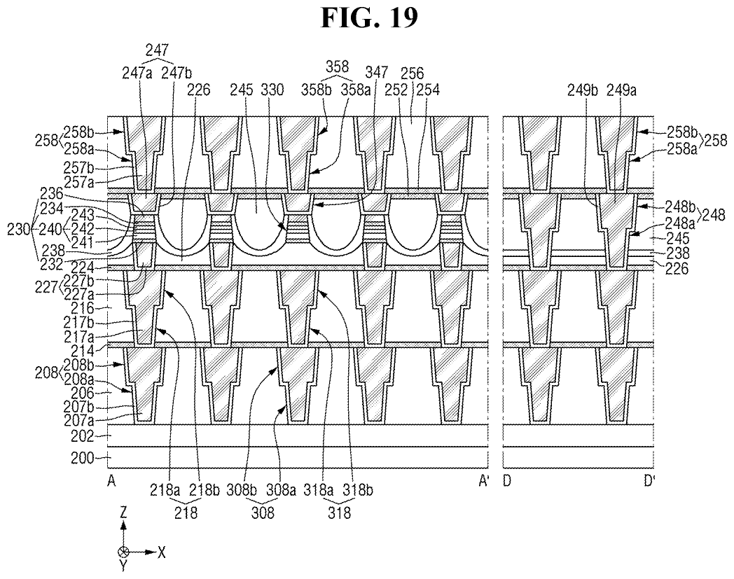

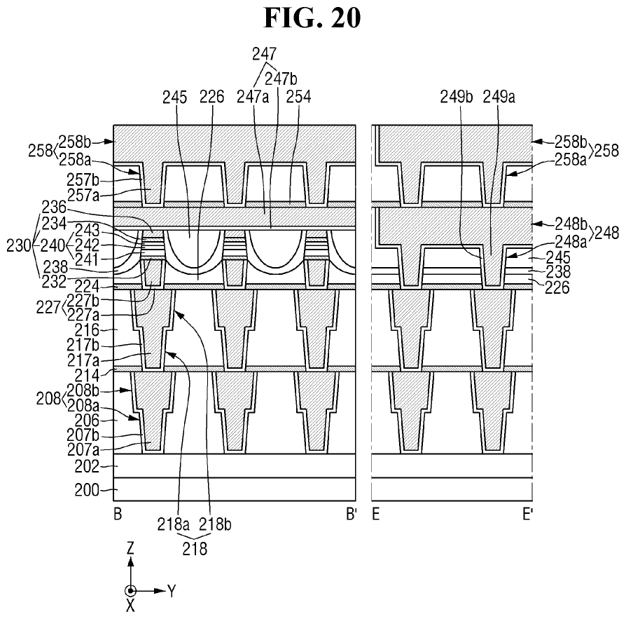

FIGS. 19 and 20 are cross-sectional views illustrating an electronic device according to some embodiments. For reference, FIG. 19 is a cross-sectional view of the electronic device taken along A-A′ and D-D′ of FIG. 7, and FIG. 20 is a cross-sectional view of the electronic device taken along B-B′ and E-E′ of FIG. 7. For convenience of explanation, repeated parts of contents explained using FIGS. 1 to 11 will be briefly explained or omitted.

Referring to FIGS. 7, 19 and 20, in the electronic device 1 according to some embodiments, the first mold layer 226 may be placed on the second etch stop film 224 on the cell region CR and the core peri region CPR. The capping film 238 may be placed on the first mold layer 226 on the cell region CR and the core peri region CPR. The capping film 238 may extend along the upper surface of the first mold layer 226 on the cell region CR and the core peri region CPR and side walls of the first and second structures 230 and 330 on the cell region CR. The second mold layer 245 may be placed on the capping film 238.

The fourth wiring structure 248 may be placed inside the second etch stop film 224, the first mold layer 226, the capping film 238, and the second mold layer 245. The fourth wiring structure 248 penetrates the second etch stop film 224, the first molding layer 226 and the capping film 238, and may be electrically connected to the second-1 wiring structure 218 of the core peri region CPR. The fourth wiring structure 248 may come into contact with the second-1 wiring structure 218 of the core peri region CPR.

In concluding the detailed description, those skilled in the art will appreciate that many variations and modifications may be made to the embodiments without substantially departing from the inventive concepts of the present disclosure. Therefore, embodiments of the disclosure are used in a generic and descriptive sense only and not for purposes of limitation.

1. A magnetic memory device comprising:
a first upper insulating layer, a second upper insulating layer, and a first mold layer that are sequentially stacked on a substrate;
a first primary wiring structure and a first secondary wiring structure that are spaced apart from each other in the first upper insulating layer;
a second wiring structure on the first primary wiring structure, in the second upper insulating layer;
a reference wiring structure on the first secondary wiring structure, in the second upper insulating layer;
a first structure on the second wiring structure;
a second structure on the reference wiring structure;
a lower electrode contact that is between the second wiring structure and the first structure, and is not between the reference wiring structure and the second structure, in the first mold layer;
a bit line structure on the first structure; and
a reference bit line structure on the second structure,
wherein the first structure and the second structure respectively comprise a lower electrode, an MTJ structure, an intermediate electrode, and an upper electrode.

2. The magnetic memory device of claim 1, wherein the reference wiring structure and the second structure are spaced apart by the first mold layer and the MTJ structure of the second structure comprises a non-functional structure.

3. The magnetic memory device of claim 1, wherein the reference wiring structure extends in a first direction.

4. The magnetic memory device of claim 3, wherein the reference wiring structure comprises a plurality of vias spaced apart from each other in a first direction, and wirings extending in the first direction on the plurality of vias.

5. The magnetic memory device of claim 1, wherein the first secondary wiring structure and the reference wiring structure are in electrical contact with each other.

6. The magnetic memory device of claim 4, wherein the bit line structure and the reference bit line structure extend in the first direction.

7. The magnetic memory device of claim 1, further comprising:
a capping film extending along an upper surface of the first mold layer, side walls of the first structure, and side walls of the second structure.

8. The magnetic memory device of claim 1, further comprising:
a third primary wiring structure between the first structure and the bit line structure; and
a third secondary wiring structure between the second structure and the reference bit line structure.

9. The magnetic memory device of claim 8, wherein the third primary wiring structure and the third secondary wiring structure comprise wirings extending in a first direction.

10. The magnetic memory device of claim 8, wherein the third primary wiring structure and the third secondary wiring structure comprise vias.

11. The magnetic memory device of claim 8, further comprising:
a second mold layer on the first mold layer;
a first etch stop film on the second mold layer; and
a second etch stop film on the first etch stop film,
wherein the third primary wiring structure and the third secondary wiring structure penetrate the second mold layer and the first etching stop film, and
the bit line structure and the reference bit line structure penetrate the second etch stop film.

12. The magnetic memory device of claim 1, wherein the first upper insulating layer, the second upper insulating layer, and the first mold layer are sequentially stacked on a first region of the substrate, wherein the substrate further comprises a second region,
the reference bit line structure is not electrically connected to the second region, and
the bit line structure is electrically connected to the second region.

13. The magnetic memory device of claim 1, wherein the first upper insulating layer, the second upper insulating layer, and the first mold layer are sequentially stacked on a first region of the substrate, wherein the substrate further comprises a second region,
the second region comprises a sense amplifier and a reference resistor;
the bit line structure is electrically connected to the sense amplifier, and
the reference wiring structure is electrically connected to the sense amplifier and the reference resistor.

14. A magnetic memory device comprising:
a first upper insulating layer, a second upper insulating layer, and a first mold layer that are sequentially stacked on a substrate;
a first wiring structure and a reference wiring structure that are spaced apart from each other in the first upper insulating layer;
a second primary wiring structure on the first wiring structure, in the second upper insulating layer;
a second secondary wiring structure on the reference wiring structure, in the second upper insulating layer;
a first structure on the second primary wiring structure;
a second structure on the second secondary wiring structure;
a lower electrode contact in the first mold layer, between the second primary wiring structure and the first structure, and between the second secondary wiring structure and the second structure;
a bit line structure on the first structure; and
a reference bit line structure on the second structure,
wherein the first structure and the second structure respectively comprise a lower electrode, an MTJ structure, an intermediate electrode, and an upper electrode.

15. The magnetic memory device of claim 14, wherein the reference wiring structure extends in a first direction and the MTJ structure of the second structure comprises a non-functional structure.

16. The magnetic memory device of claim 15, wherein the reference wiring structure comprises a plurality of vias spaced apart from each other in the first direction, and wirings extending in the first direction on the plurality of vias.

17. The magnetic memory device of claim 15, wherein the bit line structure and the reference bit line structure extend in the first direction.

18. The magnetic memory device of claim 14, further comprising:
a capping film which extends along an upper surface of the first mold layer, side walls of the first structure, and side walls of the second structure.

19. The magnetic memory device of claim 14, further comprising:
a third primary wiring structure between the first structure and the bit line structure; and
a third secondary wiring structure between the second structure and the reference bit line structure.

20-22. (canceled)

23. An electronic device comprising:
a logic region; and
a memory region electrically connected to the logic region, wherein the memory region is embedded in the electronic device, and the memory region comprises a cell region and a core peri region, and
wherein the cell region comprises:
a substrate;
a first upper insulating layer, a second upper insulating layer and a first mold layer that are sequentially stacked on the substrate;
a plurality of first primary wiring structures aligned in a first direction in the first upper insulating layer;
a plurality of first secondary wiring structures spaced apart from the plurality of first primary wiring structures in a second direction and aligned in the first direction, in the first upper insulating layer;
a plurality of second wiring structures on the plurality of first primary wiring structures, respectively, in the second upper insulating layer;
a reference wiring structure extending along the first direction and electrically connected to the plurality of first secondary wiring structures, on the plurality of first secondary wiring structures in the second upper insulating layer;
a first structure on one or more of the plurality of second wiring structures;
a second structure on the reference wiring structure;
a respective lower electrode contact between the one or more of the plurality of second wiring structures and the first structure, in the first mold layer;
a bit line structure extending in the first direction on the first structure; and
a reference bit line structure extending in the first direction on the second structure,
wherein the reference wiring structure and the second structure are spaced apart by the first mold layer, and
wherein the first and second structures respectively comprise a lower electrode, an MTJ structure, an intermediate electrode, and an upper electrode.

24. (canceled)

25. (canceled)
